(19) United States
(12) Patent Application Publication
(10) Pub. No.: US 2006/0145247 A1
(43) Pub. Date: Jul. 6, 2006

(54) Trench transistor and method for producing it

(76) Inventors: Markus Zundel, Egmating (DE); Franz Hirler, Isen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/288,519

(22) Filed: Nov. 29, 2005

(30) Foreign Application Priority Data
Nov. 30, 2004 (DE) 10 2004 057 791.9

(51) Int. Cl. H01L 29/94

(52) U.S. Cl. 257/330

(57) ABSTRACT

A trench transistor and method of making a trench transistor is disclosed. In one embodiment, the trench transistor has a semiconductor body in which a plurality of cell array trenches separated from one another by mesa regions are formed. Electrodes are embedded in the cell array trenches. A source region, a body region and also a body contact region are in each case provided in the mesa regions. The electrodes of a plurality of cell array trenches are at source potential. At least some body contact regions are embodied in the form of a layer which forms at least one part of an upper region of the inner wall of a cell array trench, the electrode of which is at source potential, and whose horizontal extent is less than half of the horizontal extent of a mesa region.

### CROSS-REFERENCE TO RELATED APPLICATIONS

This Utility patent application claims priority to German Patent Application No. DE 10 2004 057 791.9 filed on Nov. 30, 2004, which is incorporated herein by reference.

### FIELD OF THE INVENTION

The invention relates to a trench transistor and a method for producing it.

### BACKGROUND

Trench transistors are used in a multiplicity of technical products and are generally designed such that they have a low on resistivity Rₒₙ·A (Rₒₙ=on resistance; A=active chip area), since a low on resistivity entails a low power loss. However, trench transistors can also be optimized with regard to other parameters. If, by way of example, low-loss and fast switching is intended to be made possible, the gate capacitances should turn out to be as low as possible. In order to obtain good breakdown properties (“Avalanche strength”), on the other hand, it is necessary to keep the space requirement of the trench transistor as small as possible and also to ensure a good electrical connection of the body regions to the power supply.

The electrical connection of the body regions to the power supply is generally effected via highly conductive body contact regions. The fabrication of the body contact regions proves to be difficult in trench transistors having small dimensions (“dense trench transistors”, width of the mesa region is less than the width of the trenches), since only little space is available for the body contact regions (only part of the surface of the mesa regions formed between the trenches can be utilized since the rest of the surface is required for the source regions), but the body contact regions are generally outdiffused, and the outdiffusion entails a high lateral space requirement of the body contact regions.

### SUMMARY

The present invention provides a trench transistor. In one embodiment, the present invention includes a trench transistor, having a semiconductor body in which a plurality of cell array trenches separated from one another by mesa regions are formed. Electrodes are embedded in the cell array trenches, a source region, a body region and also a body contact region in each case being provided in the mesa regions. The electrodes of a plurality of cell array trenches are at source potential. At least some body contact regions are embodied in the form of a layer which forms a part of the upper region of the inner wall of a cell array trench, the electrode of which is at source potential, and whose horizontal extent is less than half of the horizontal extent of a mesa region.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a first process step of a known method for fabricating a trench transistor.

FIG. 2 illustrates a second process of the known method for fabricating a trench transistor.

FIG. 3 illustrates a third process of the known method for fabricating a trench transistor.

FIG. 4 illustrates a fourth process of the known method for fabricating a trench transistor.

FIG. 5 illustrates a fifth process of the known method for fabricating a trench transistor.

FIG. 6 illustrates a sixth process of the known method for fabricating a trench transistor.

FIG. 7 illustrates a seventh process of the known method for fabricating a trench transistor.

FIG. 8 illustrates an eighth process of the known method for fabricating a trench transistor.

FIG. 9 illustrates a ninth process of the known method for fabricating a trench transistor.

FIG. 10 illustrates a tenth process of the known method for fabricating a trench transistor.

FIG. 11 illustrates an eleventh process of the known method for = fabricating a trench transistor.

FIG. 12 illustrates a twelfth process of the known method for fabricating a trench transistor.

FIG. 13 illustrates a thirteenth process of the known method for fabricating a trench transistor.

FIG. 14 illustrates a first process of one preferred embodiment of a method according to the invention for fabricating body regions, body contact regions and also source regions.

FIG. 15 illustrates a second process of one preferred embodiment of a method according to the invention for fabricating body regions, body contact regions and also source regions.

FIG. 16 illustrates a third process of one embodiment of the method according to the invention for fabricating body regions, body contact regions and also source regions.

FIG. 17 illustrates a fourth process of one embodiment of the method according to the invention for fabricating body regions, body contact regions and also source regions.

FIG. 18 illustrates a fifth process of one embodiment of the method according to the invention for fabricating body regions, body contact regions and also source regions.

FIG. 19 illustrates a sixth process of one embodiment of the method according to the invention for fabricating body regions, body contact regions and also source regions.

FIG. 20 illustrates a seventh process of one embodiment of the method according to the invention for fabricating body regions, body contact regions and also source regions.

FIG. 21 illustrates a eighth process of one embodiment of the method according to the invention for fabricating body regions, body contact regions and also source regions.

FIG. 22 illustrates a ninth process of one embodiment of the method according to the invention for fabricating body regions, body contact regions and also source regions.

FIG. 23 illustrates a tenth process of one embodiment of the method according to the invention for fabricating body regions, body contact regions and also source regions.

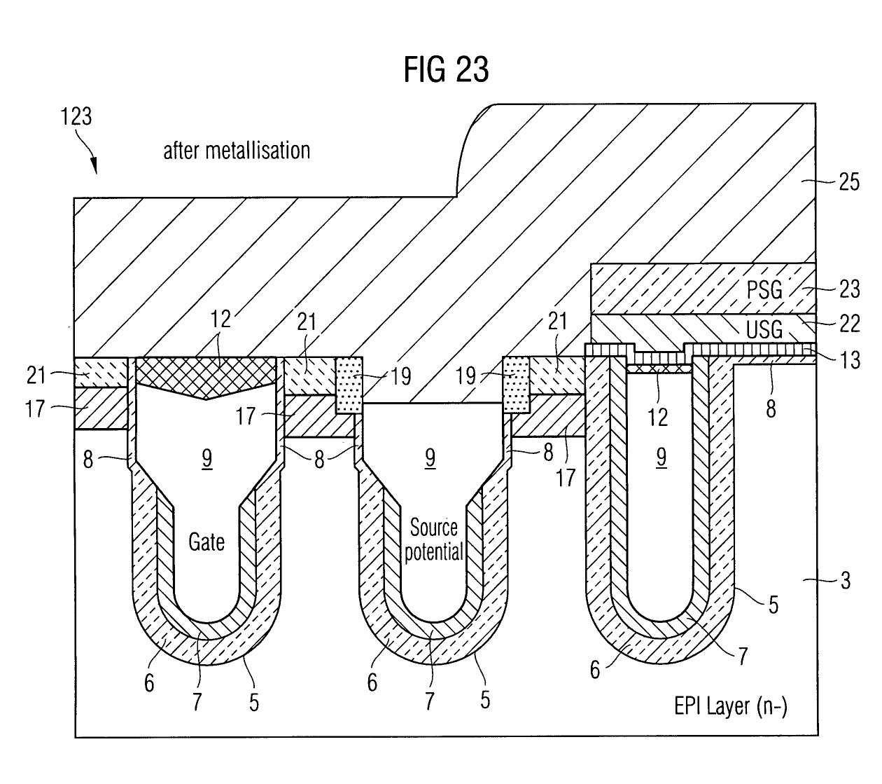

FIG. 24 illustrates an eleventh process of one embodiment of the method according to the invention for fabricating body regions, body contact regions and also source regions.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a trench transistor whose body contact regions enable a good, reliable connection of the body regions to the power supply despite small dimensions of the trench transistor (“dense trench transistors”). Furthermore, the present invention provides a method for fabricating the source regions, body regions and also body contact regions in the mesa regions of the trench transistor.

In one embodiment, the trench transistor according to the invention has a semiconductor body, in which a plurality of cell array trenches separated from one another by mesa regions are formed. Electrodes are embedded in the cell array trenches. A source region, a body region and also a body contact region are in each case provided in the mesa regions. The electrodes of a plurality of cell array trenches are at source potential. At least some body contact regions are embodied in the form of a layer which forms at least one part of the upper region of the inner wall of a cell array trench, the electrode of which is at source potential, and whose horizontal extent is less than half of the horizontal extent of a mesa region.

According to one embodiment of the invention, the inner walls of the cell array trenches whose electrodes are at source potential are configured as body contact regions. Since, in principle, an arbitrarily sized region of the inner walls can be used for forming the body contact regions, on the one hand a good contact-connection of the body regions is ensured, and on the other hand the body contact region has to take up only a small part of the width of the mesa regions. This has the advantage that a great part of the width of the mesa regions is available for forming the source regions, whereby the dimensions of the trench transistors (in particular of the mesa regions) can be reduced further without having to accept losses in the quality of the electrical connections by virtue of the body contact regions.

“Mesa region” is understood to be the region of the semiconductor body between two cell array trenches.

In one embodiment, at least some body contact regions adjoin the surface of the respective mesa region. This is not absolutely necessary, however. It suffices for the body contact regions to be “buried” below the surface of the respective mesa region. In order nevertheless to ensure a sufficient contact-connection of the body regions, at least in this case the vertical extent of the body contact regions should turn out to be higher than the vertical extent of the source regions.

In accordance with one embodiment of the invention, accordingly, the source regions are essentially contact-connected via the surface of the mesa regions, and the body contact regions are essentially contact-connected via the inner walls of the cell array trenches whose electrodes are at source potential.

The invention can be employed in particular in connection with dense trench transistors (transistors having a high integration density): dense trench transistors enable a high doping of the drift region and thus a low on resistivity, but can on the other hand, in the off state, be completely depleted (of charge) on account of the small width of the mesa regions and thus enable a high avalanche strength.

The cell array trenches in which electrodes at source potential are embedded serve for reducing the gate capacitance and thus enable fast and precise switching of the trench transistor. In principle, electrodes of any desired cell array trenches can be connected to source potential. It is particularly advantageous, however, if the cell array trenches in which electrodes at gate potential are embedded alternate with cell array trenches in which electrodes at gate potential are embedded.

The invention furthermore provides a method for fabricating the source regions, body regions and also body contact regions in the mesa regions of a trench transistor according to the invention, which method, proceeding from a semiconductor body, in which are formed cell array trenches containing electrodes insulated from the semiconductor body.

Firstly, body regions are formed in the upper region of the mesa regions in such a way that the body regions extend over the entire width of the mesa regions (that is to say “fill” the upper region of the mesa regions). This is followed by producing a cell array trench masking configured such that at least the cell array trenches in which electrodes at gate potential are provided are masked, but at least one region of each body region adjoining these cell array trenches is uncovered. The cell array trench masking should not cover at least the inner walls of the cell array trenches containing electrodes at source potential. The body contact regions are then formed by virtue of dopants being applied to the uncovered regions of the body regions, in particular the regions of the body regions which form inner walls of the unmasked cell array trenches, an oblique implantation or a coating process being used for application to the inner walls of the unmasked cell array trenches. The cell array trench masking is subsequently removed and a further cell array trench masking is produced, which is configured such that at least the cell array trenches in which electrodes at source potential are provided are masked, but at least one region of each body region and/or body contact region adjacent to these cell array trenches is uncovered. The source regions are then produced by application to the uncovered regions of the body regions. A standard implantation is used for this purpose.

One aspect of the method according to the invention is producing the body contact regions by means of an oblique implantation (the implantation angle is greater than 10° and is preferably between 30° and 45°), but producing the source regions by means of a standard implantation (implantation angle lies between 0° and 10°).

In one embodiment, the cell array trench masking for masking the cell array trenches in which electrodes at source potential are provided is essentially complementary to the cell array trench masking for masking the cell array trenches in which electrodes at gate potential are provided. The cell array trench masking for masking the cell array trenches in which electrodes at source potential are provided should cover less than half of the width of the mesa regions adjoining these cell array trenches. This ensures that the width of the source regions is greater than the width of the body contact regions.

The method according to the invention makes it possible to fabricate trench transistors having very narrow mesa regions in conjunction with relatively large contact regions for source and body contact regions.

In the description, identical or mutually corresponding regions, components or component groups are identified by the same reference numerals. Furthermore, in all of the embodiments the doping types can be interchanged with one another, that is to say that p-type regions can be replaced by n-type regions, and vice versa.

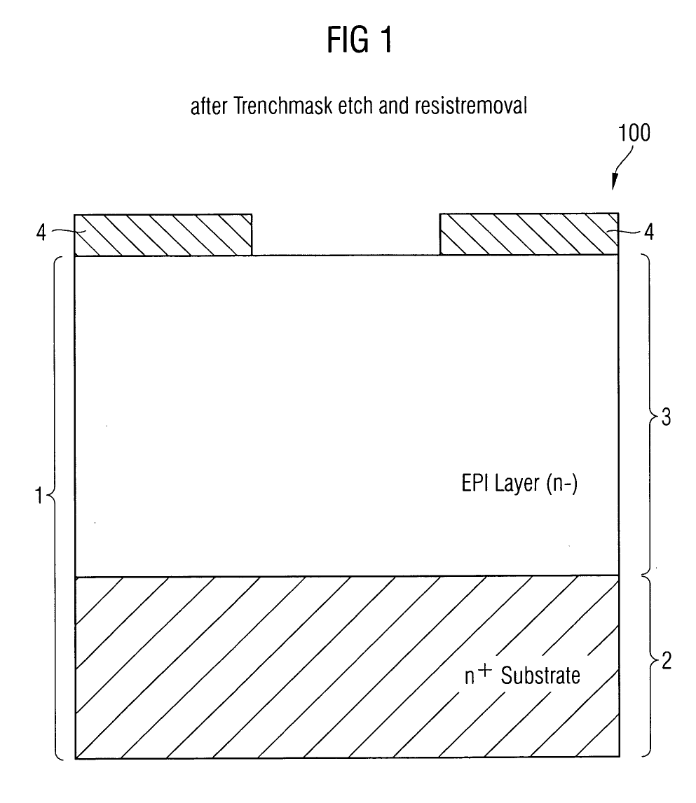

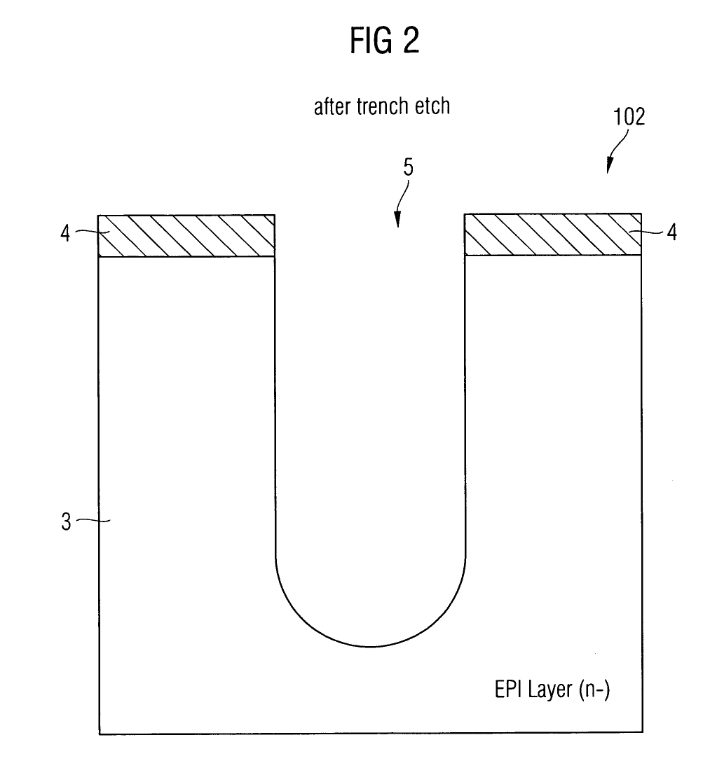

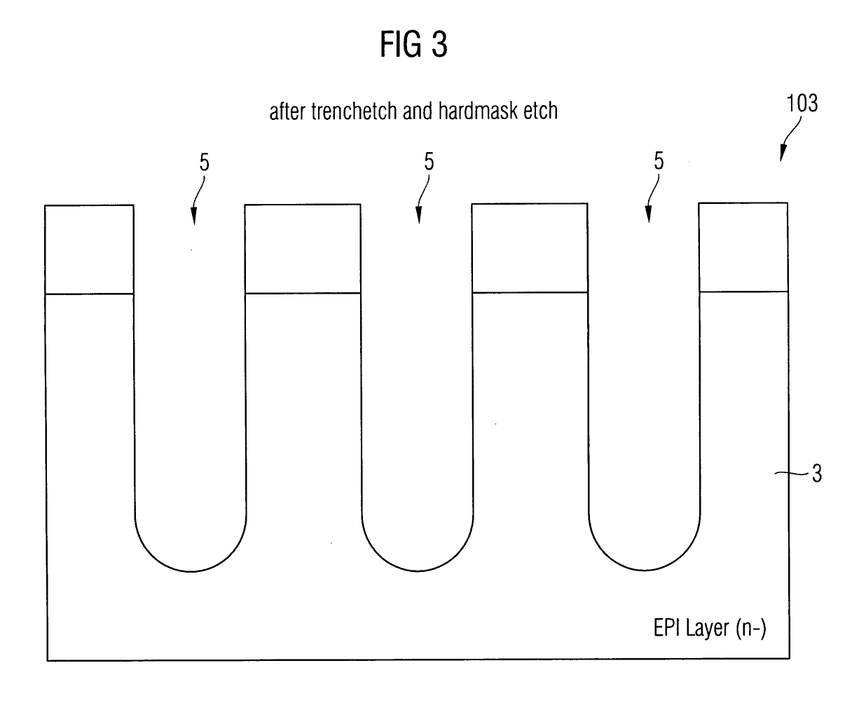

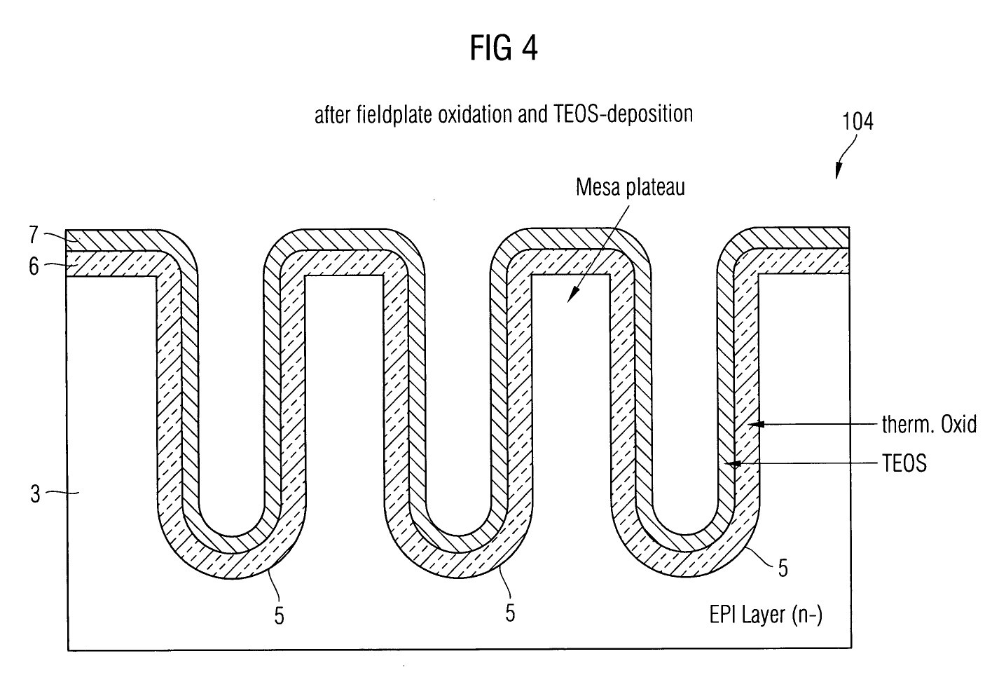

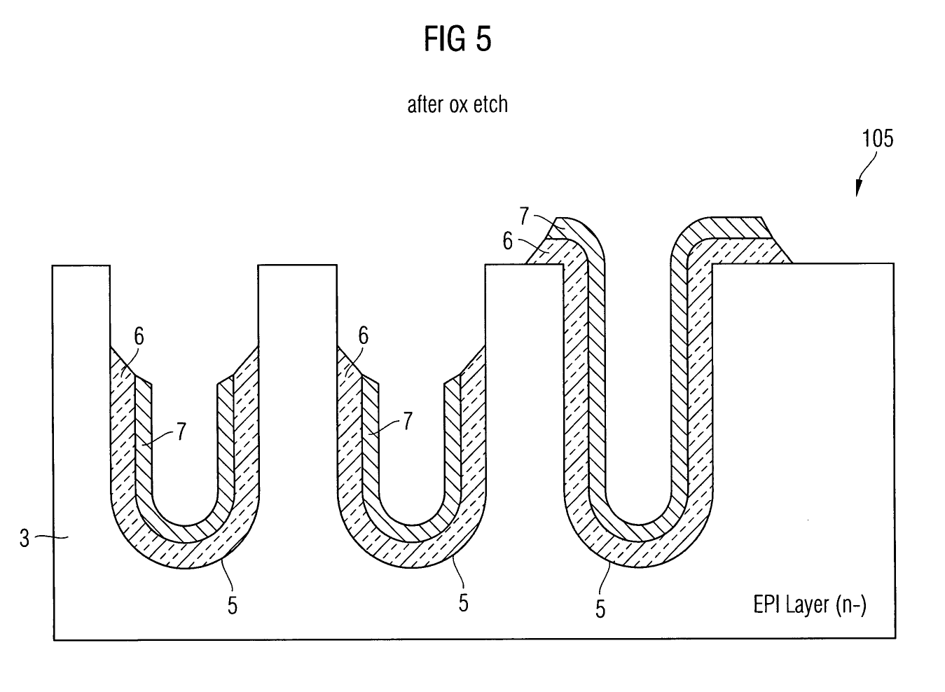

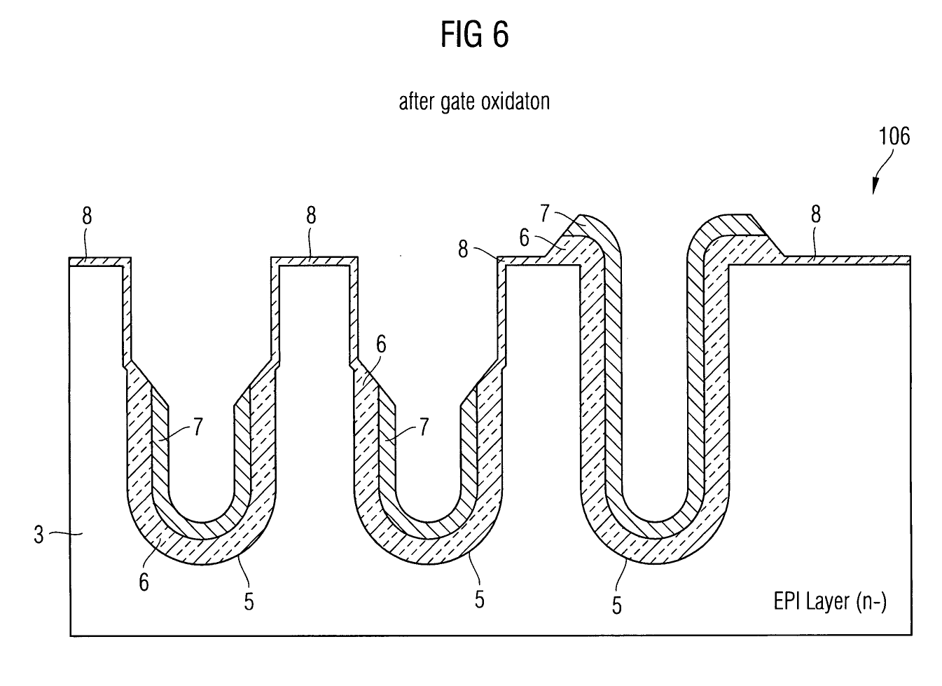

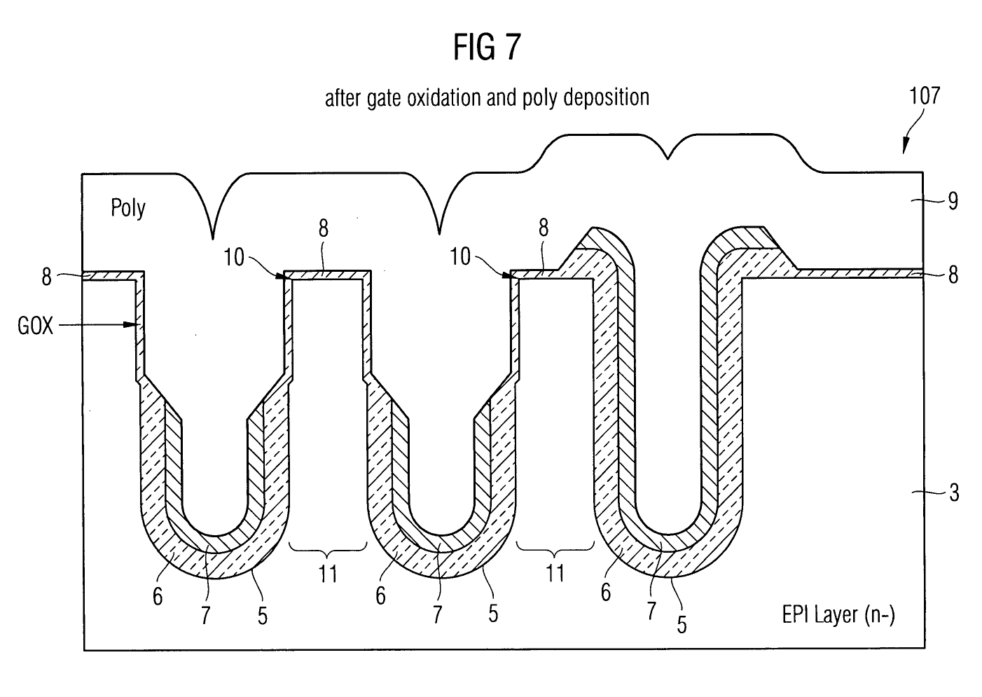

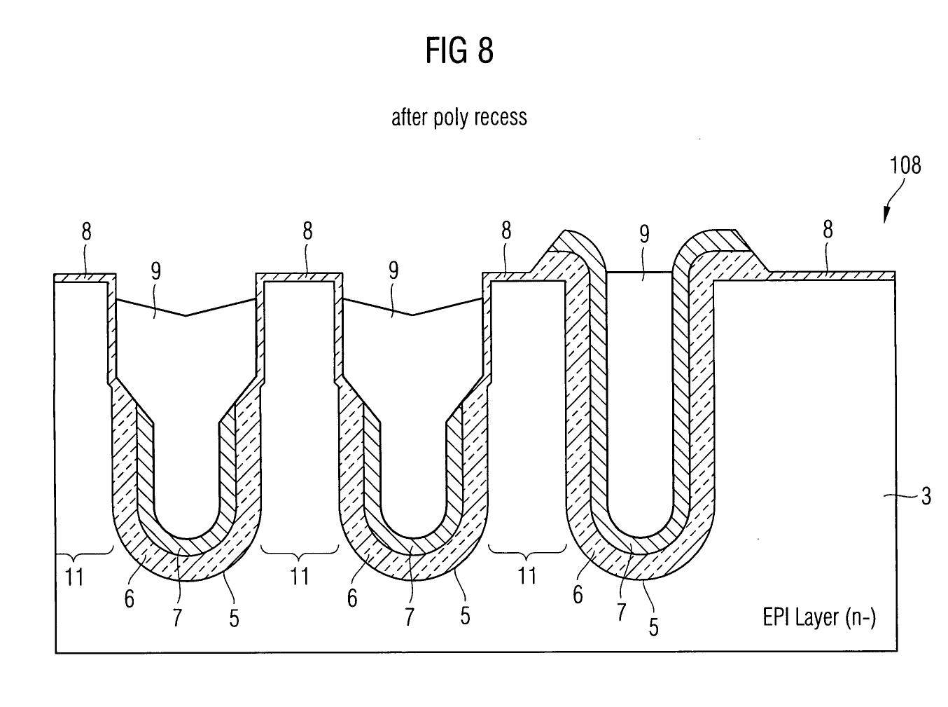

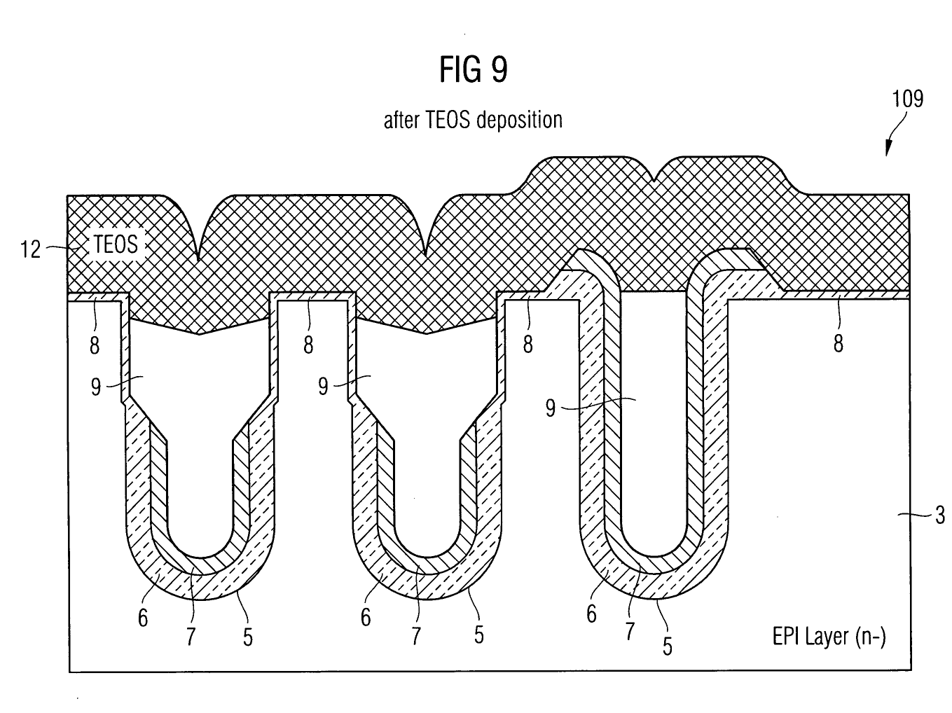

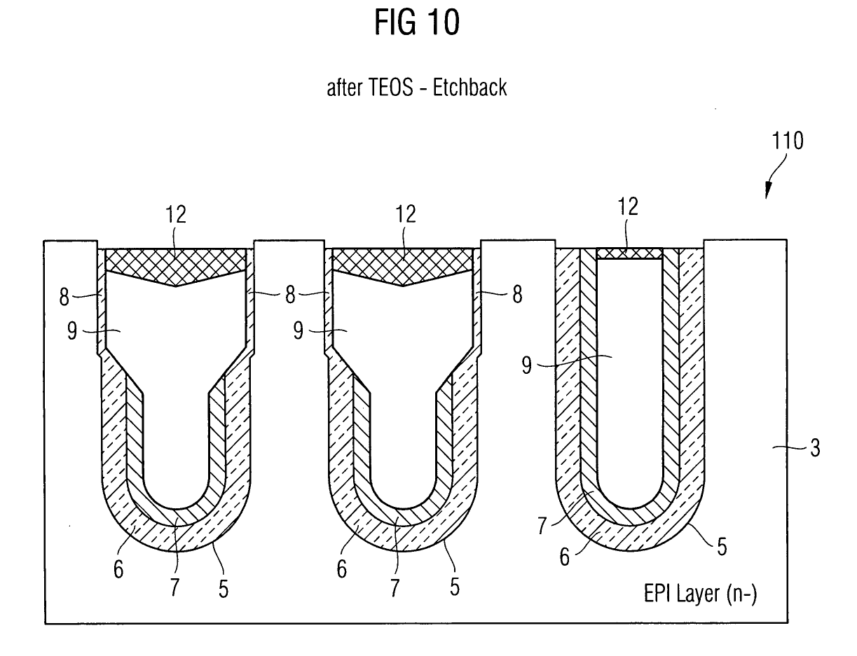

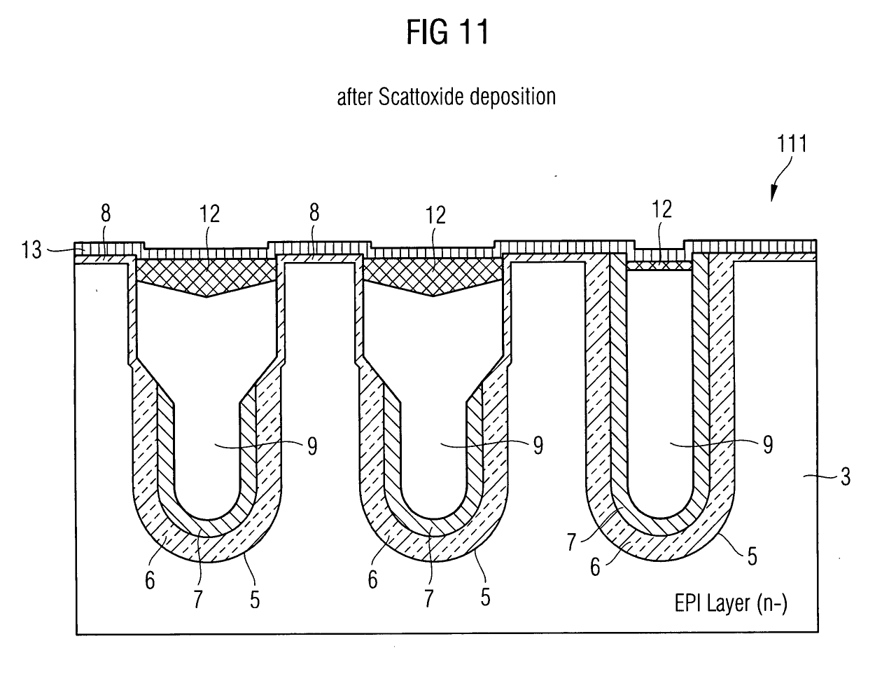

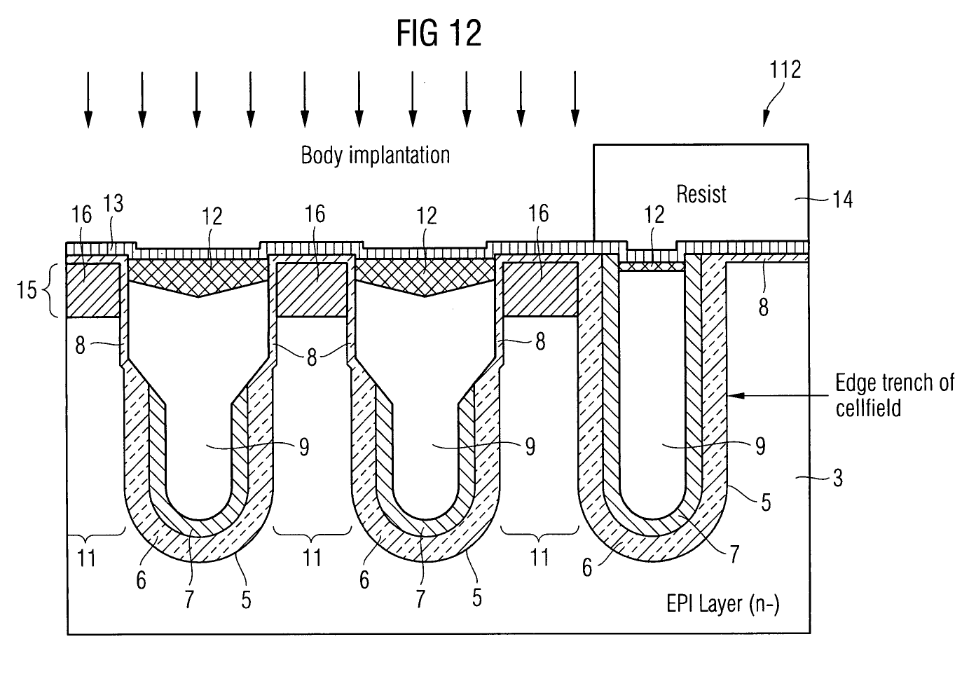

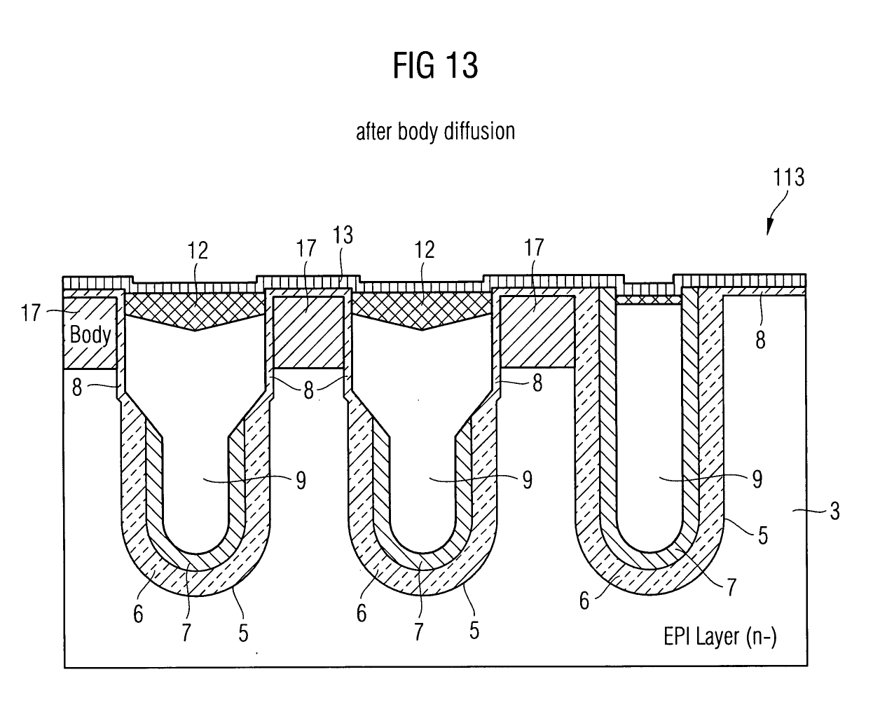

FIG. 1 illustrates a first process 100 of a known trench transistor fabrication method. A hard mask 4 (preferably TEOS) is applied on the surface of a semiconductor body 1, which comprises an n⁺-doped substrate layer 2 and also an n⁻-doped epitaxial layer 3 applied thereon, and is subsequently patterned. Afterwards, in a process 102 (FIG. 2) the epitaxial layer 3 is etched using the mask 4, so that a trench 5 is produced within the epitaxial layer 3. Afterwards, the mask 4 is removed in a further process 103 (FIG. 3). In a further process step 104 (FIG. 4), an insulation layer (generally an oxide) 6 is produced on the surface of the epitaxial layer 3 and a further insulation layer 7 (generally TEOS) is deposited thereon. In a further process (FIG. 5), the insulation layers 6 and 7 are etched back into the trenches 5, apart from the right-hand trench 5 (which is an edge trench). In process 106 (FIG. 6), an insulation layer 8 is then produced on the uncovered surface of the epitaxial layer 3 (preferably by thermal oxidation of the surface of the epitaxial layer 3). The remaining free spaces within the trenches 5 are then (FIG. 7) filled with a conductive material (generally polysilicon 9), the conductive material 9 also covering the insulation layer 8 present on the surfaces 10 of the mesa regions. In process 108 (FIG. 8), the layer made of conductive material 9 is etched back such that it is etched back right into the trenches 5 with the exception of the edge trench (right-hand trench 5), so that the insulation layer 8 is uncovered in the upper regions of the mesa regions 11. In process 109 (FIG. 9), the surface of the structure shown in FIG. 8 is coated with a layer made of insulating material 12 (preferably TEOS). In process 110 (FIG. 10), the layer made of insulating material 12, the insulation layer 6 and also the insulation layer 7 are etched back into the trenches 5. In process 111 (FIG. 11), the uncovered surfaces of the mesa regions 11 are coated with a screen oxide layer 13. In process 112 (FIG. 12), dopants are introduced within the mesa regions 11 by means of implantation. The edge trench (the right-hand trench 5), and also the region of the epitaxial layer 3 situated to the right thereof are covered with a mask 14 beforehand. In process 113 (FIG. 13), the dopants 16 introduced into the upper regions 15 of the mesa regions are outdiffused by means of a heat treatment to form body regions 17.

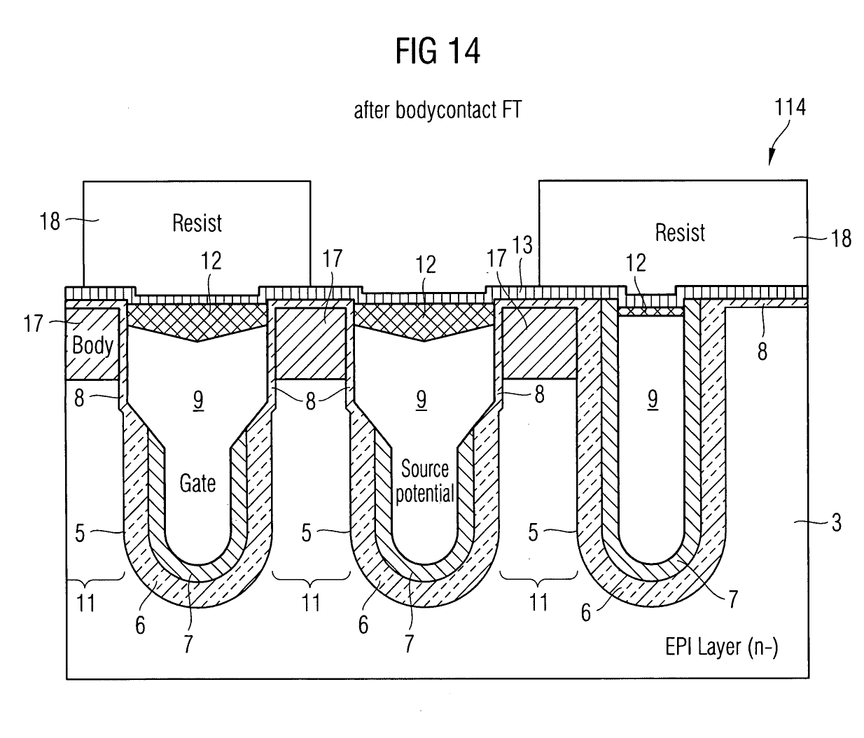

The fabrication method described with reference to FIGS. 1 to 13 is known. The first process of the fabrication method according to the invention is illustrated in FIG. 14 (process step 114).

A mask 18 is applied on the surface of the structure illustrated in FIG. 13, which mask is patterned in such a way that every second trench 5 and also parts of the mesa regions 11 adjoining the latter are covered. The blocks of electrically conductive material 9 form electrodes within the trenches 5, the electrodes of every second trench being at gate potential, and the electrodes of the remaining trenches being at source potential. In FIG. 14, the electrode of the left-hand trench is at gate potential, and the electrode of the middle trench 5 is at source potential. The electrode of the right-hand trench 5 can be connected to a suitable edge potential.

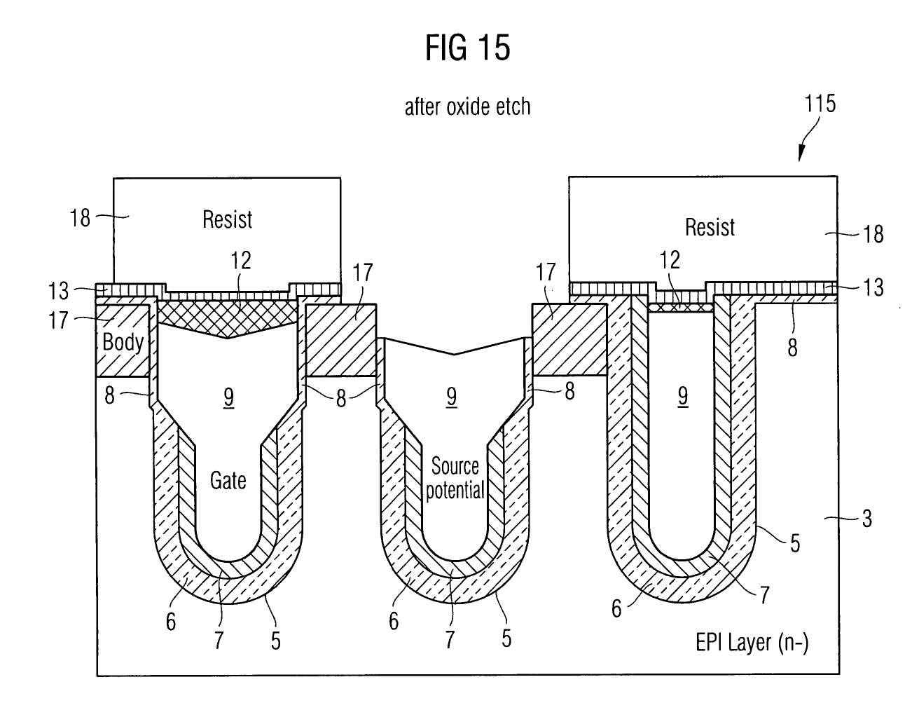

In process 115 (FIG. 15), the parts of the layers 12, 13 and 8 that are not covered by the mask 18 are removed by means of an etching process.

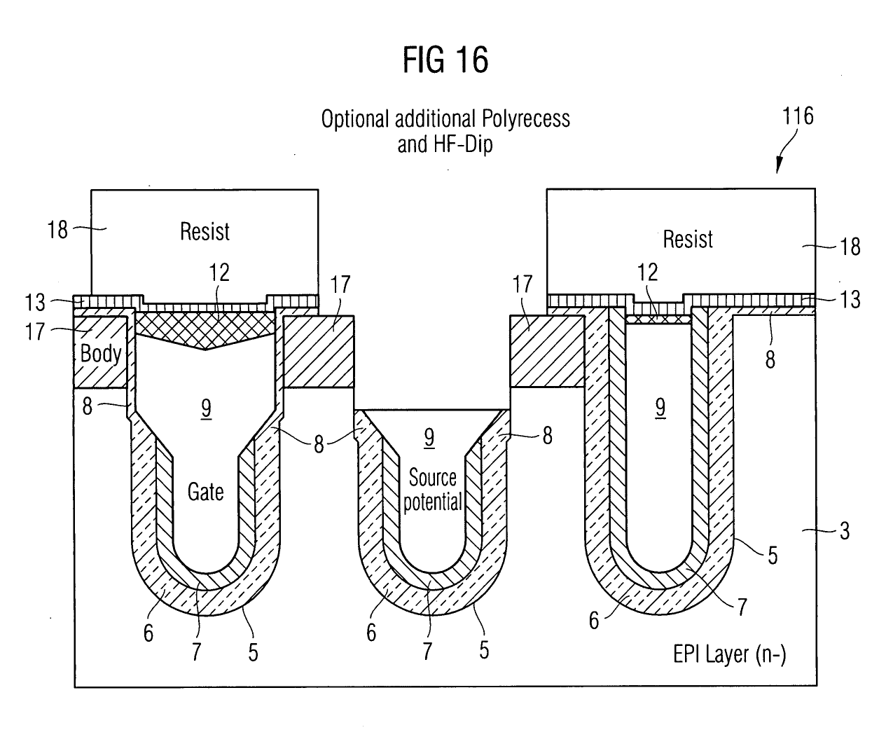

In process 116 (FIG. 16), the parts of the insulation layer 8 and also of the conductive layer 9 that are not covered by the mask 18 are etched back further.

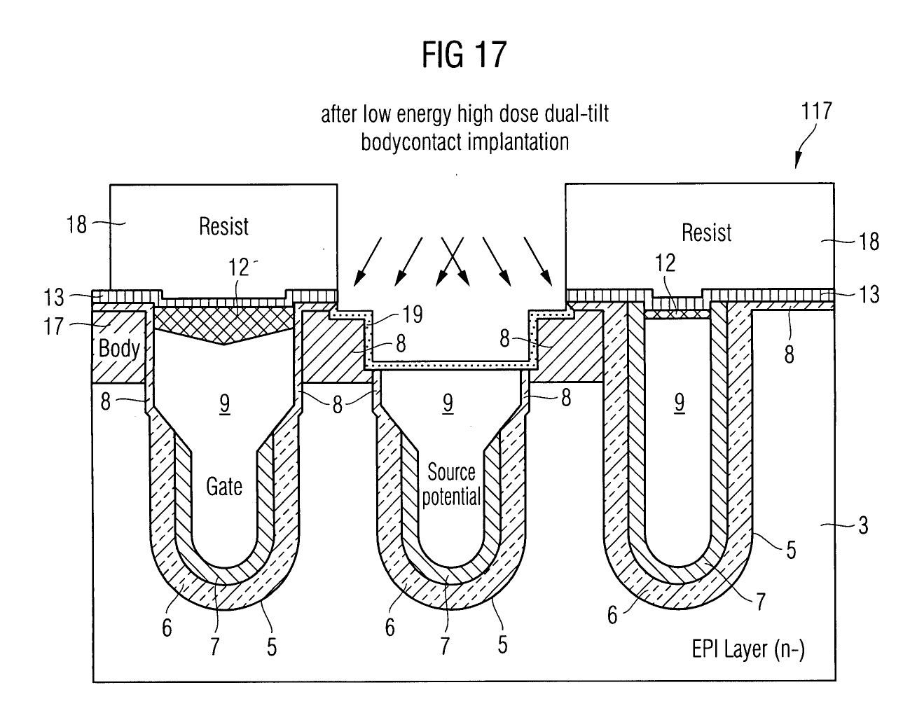

In process 117 (FIG. 17), dopants are introduced into the parts of the body regions 17 that are not covered by the mask 18, and also into the surface of the conductive layer 9, by means of an oblique implantation, whereby body contact regions 19 are produced. The oblique implantation is preferably effected at an implantation angle of 45° and has a relatively high dose in order to obtain a lowest possible body contact resistance.

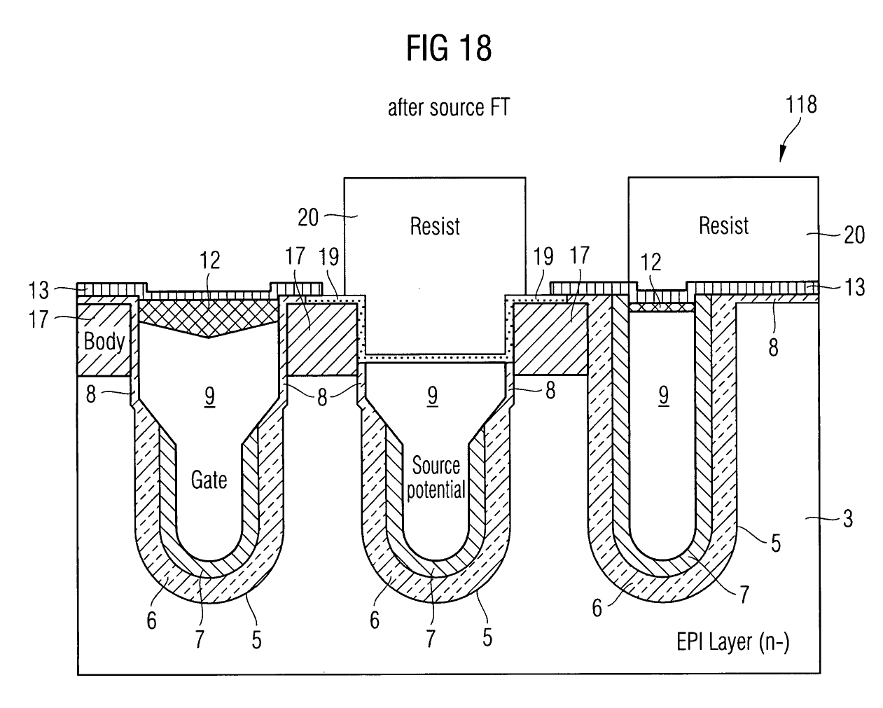

In process step (FIG. 18), the mask 18 is removed and a mask 20 is applied to the surface of the structure shown in FIG. 17. The mask 20 covers the trenches 5 whose electrodes are at source potential, and also parts of the mesa regions 11 adjoining these parts (that is to say parts of the horizontally running regions of the body contact regions 19). Furthermore, the mask 20 covers the edge trench and also that part of the epitaxial layer 3 which lies to the right of said edge trench. The mask 20 is essentially complementary to the mask 18, that is to say that regions which remain uncovered by the mask 18 are covered by the mask 20, and vice versa.

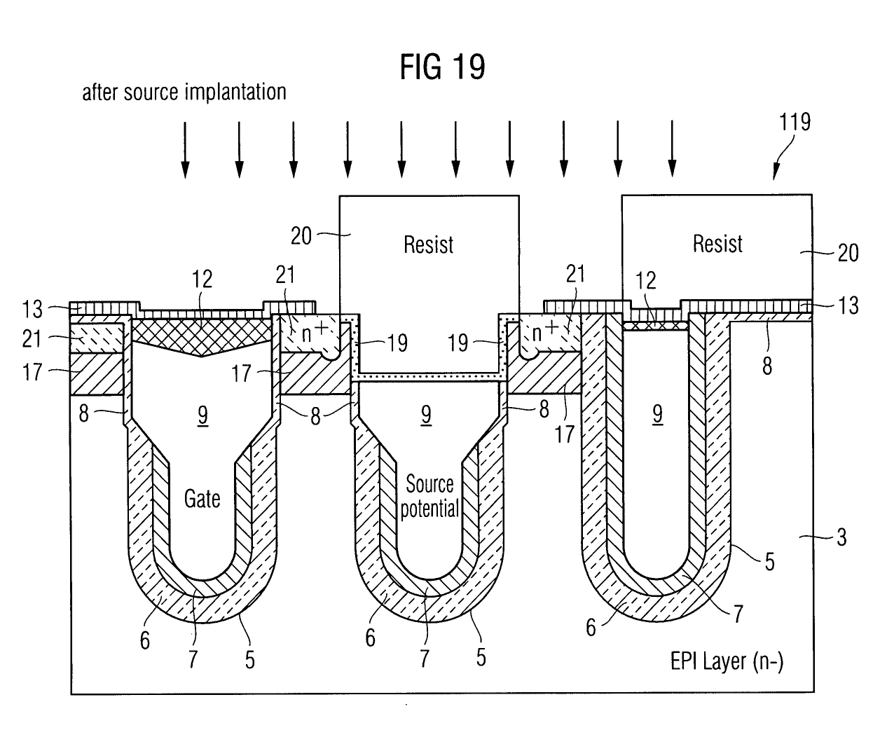

In process 119 (FIG. 19), source regions 21 are produced in the body regions 17 by means of a normal implantation (implantation angle lies between 0° and 10°). In this case, the horizontal extents of the individual regions of the mask 20 determine the horizontal extents of the source regions 21 and are chosen such that the horizontal extents of the source regions 21 are more than half of the horizontal extents of the mesa regions 11. Thus, both the body regions 19 and the source regions 21 have large outer contact areas.

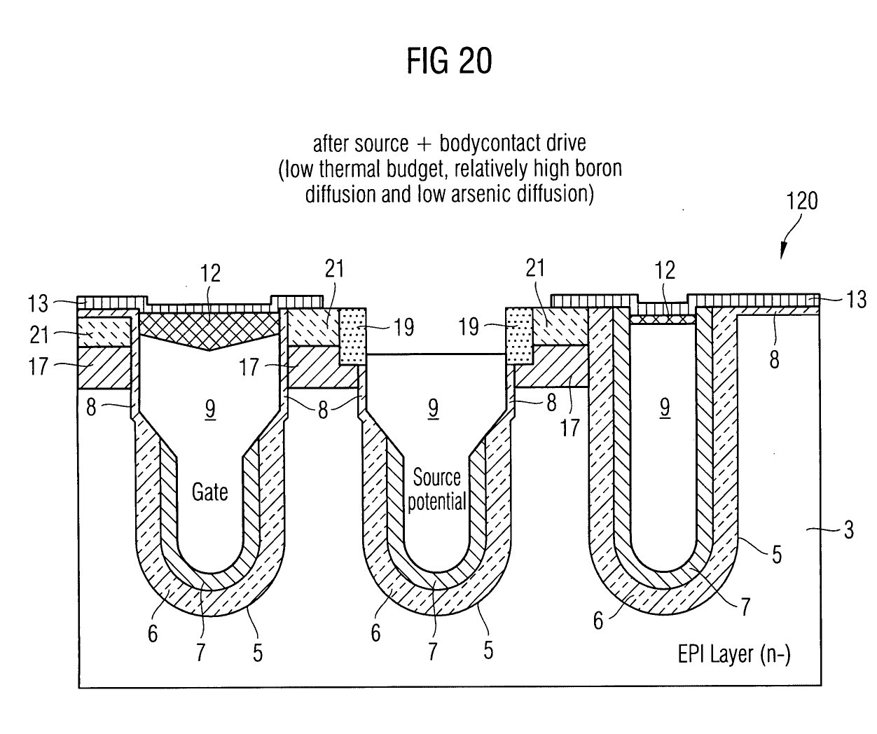

In process 120 (FIG. 20), the body contact regions 19 and also the source regions 21 are outdiffused, with the result that the structure shown in FIG. 20 arises. The mask 20 is removed prior to the outdiffusion.

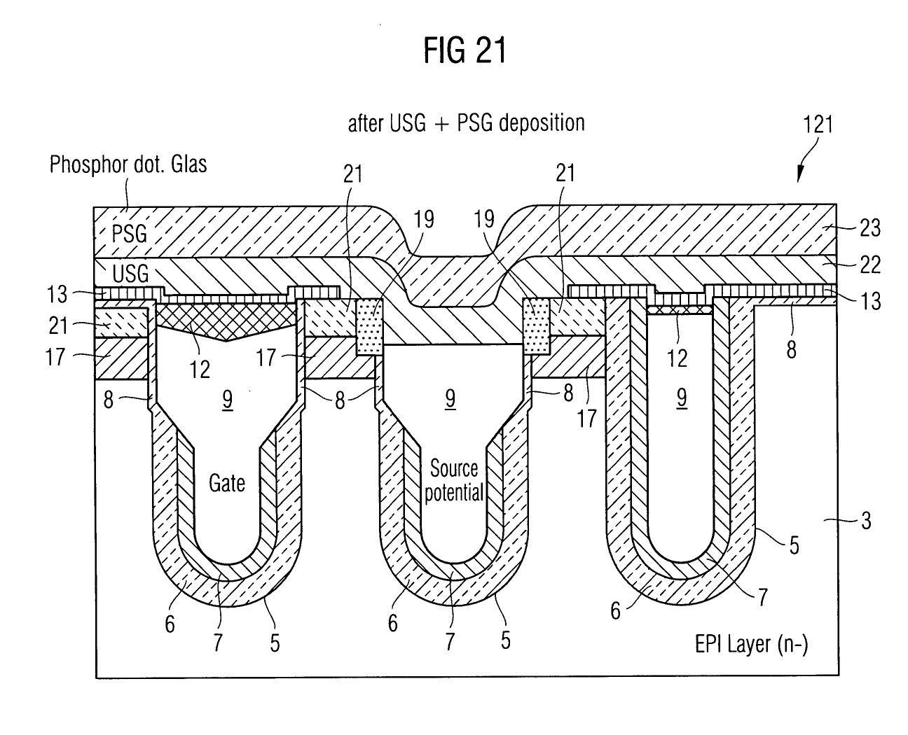

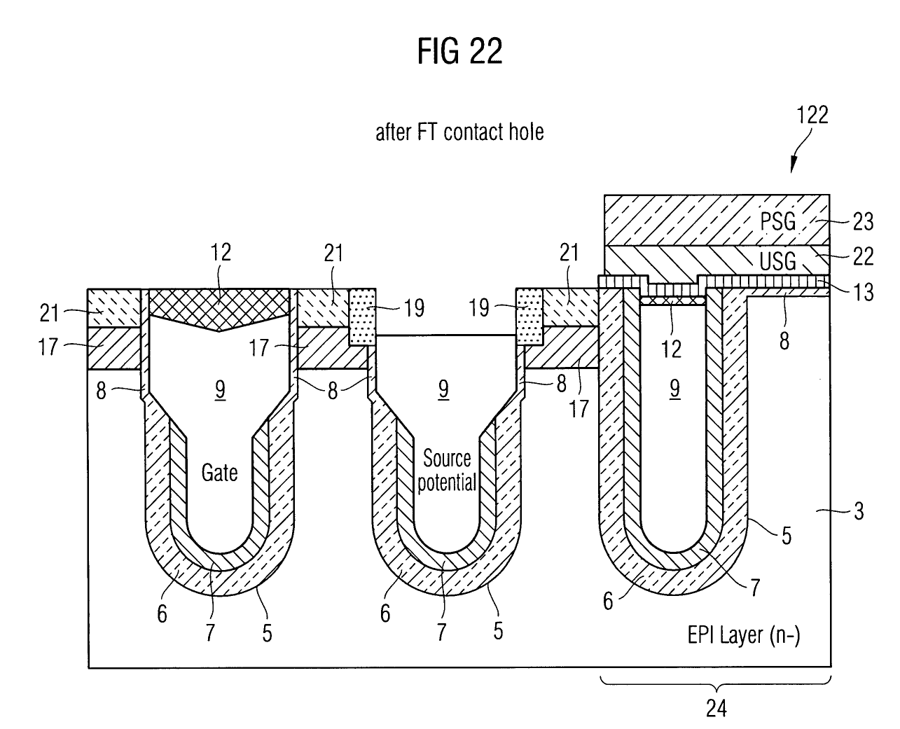

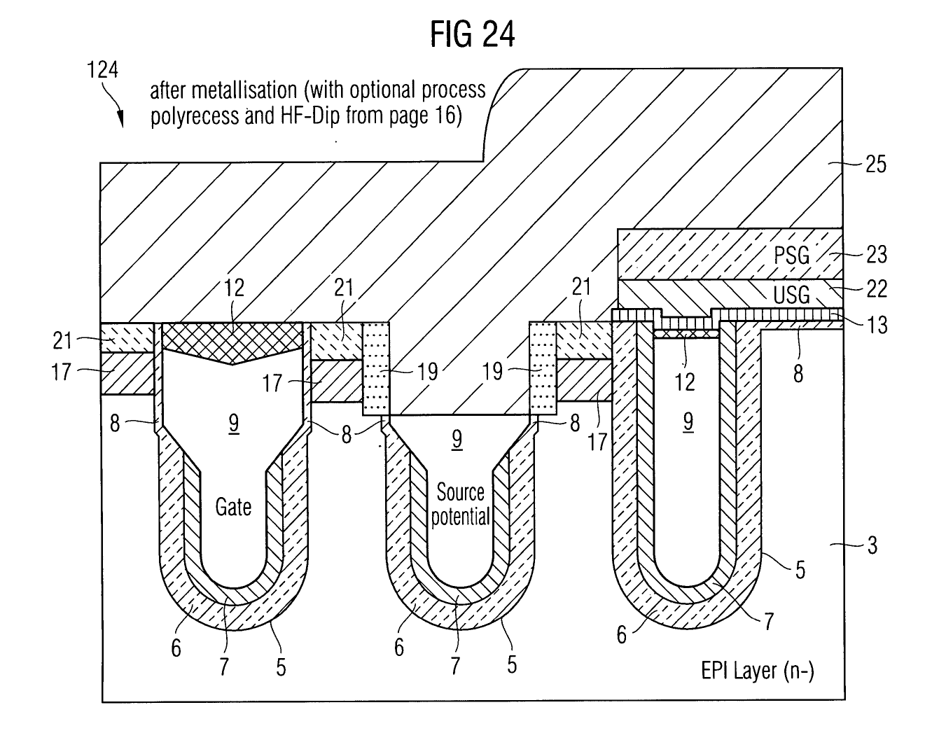

In process 121 (FIG. 21), a layer made of undoped silicate glass 22 is deposited on the surface of the structure shown in FIG. 20, and a layer 23 made of phosphorus-doped glass is deposited thereon. In process 122 (FIG. 22), the layers 22 and 23 are removed again apart from an edge region 24, for example by means of an etching process, and the insulation layer 13 is furthermore removed apart from the edge region 24. A metallization layer 25 is then deposited onto the surface of the structure illustrated in FIG. 22, whereby the device is completed. If process 116 (additional etching-back) shown in FIG. 16 is carried out, then the structure shown in FIG. 24 is produced (the body contact regions 19 project deeper into the epitaxial layer 3).

Further aspects of the invention will be explained in the description below.

As has already been mentioned, in the development of new generations of DMOS power transistors, in particular of trench transistors, reducing the on resistivity (“on-state resistivity”) Rₒₙ·A and reducing the gate capacitances are of great significance for low-loss and fast switching. If, in addition, good breakdown properties or good avalanche strength are also intended to be realized, it is advantageous for the transistor cells to be optimized with regard to smallest possible space requirement, lowest possible gate capacitances and best possible body connection. The formation of good body connections is difficult on account of the lateral outdiffusion of the body connection dopants and the associated relatively large space requirement in the case of a dense trench concept.

Previous concepts for reducing the Rₒₙ·A are aimed at packing the trenches as densely as possible. In this case, there are various approaches for configuring the source regions and body connection regions despite small dimensions of the mesa regions between the trenches (typically approximately 500 nm wide).

One possibility is to configure source regions and body connection regions as transverse strips (transverse strips run 90° to the trench direction). What is disadvantageous in this case is that, on account of the required avalanche strength, the distance between the body strips is a maximum of approximately 2 μm and the maximum channel width that can be realized is thereby limited. A further disadvantage is the high gate capacitances, since each trench is active (that is to say connected to gate potential).

A further possibility is to embody source regions and body contact regions as strips, a source region strip and a body contact region strip which run parallel to the longitudinal orientation of the mesa regions and alongside one another being formed in each case within a mesa region. In accordance with the invention, the source connection is essentially formed on the mesa surface and the body contact connection (body contact region) is essentially formed in the trench sidewall of the inactive trenches (that is to say trenches that are not at gate potential but rather at source potential). This means that more than twice the area is available to the two connections, compared with embodiments in which the two connections are introduced into the mesa surface. The method proposed furthermore has the advantage that a very high body contact dose can be introduced into the trenches down to the depth of the polyrecess by trench sidewall implantation and very good avalanche strength can thus be achieved.

One essential aspect of the invention, accordingly, in the case of a dense trench transistor optimized in respect of gate capacitances and Rₒₙ·A, is for the source connection essentially to be formed on the mesa surface and the body connection essentially to be formed in the trench sidewall of the inactive trenches (that is to say the trenches that are not at gate potential but rather, for example, at source potential).

The method according to the invention begins with process 114. Using a phototechnology, the body contact is applied in such a way that those trenches which are at gate potential later are covered with resist. The resist edge is aligned with the mesa centre with an accuracy of preferably approximately ±100 nm given resist dimension fluctuations of likewise preferably ±100 nm. This ensures, in the case of a mesa having a width of approximately 500 nm, that the resist edge is situated on the mesa surface. In process step 115, at the uncovered trenches, the TEOS (tetraethyl orthosilicate) is removed on the poly. A further polyrecess and an HF dip (short hydrofluoric acid etching) may optionally be carried out (process step 116) in order to locate the polyrecess/oxide recess even deeper in these trenches in order later to obtain more sidewall body contact area.

In process 117, there follows a body contact implantation at low energy (space-saving, small penetration depth) and with a relatively high dose (for lowest possible body contact resistance) in the “45° tilt dual mode” (implantation is effected by radiating in from two directions at an angle of approximately 45°), in order to effect implantation into the trench sidewall, or in the “45° tilt quad mode” (implantation is effected by radiating in from four directions at an angle of approximately 45°) (in the case of trench strips in different directions e.g. for edge termination).

In process 118, using phototechnology, a source contact mask is produced, which is essentially complementary to the body contact mask and the resist edge of which may be slightly offset from the mesa centre to the side towards the trench that is at source potential later.

What is achieved by process 119 is that the subsequent source implantation tends to reach into a larger region of the mesa surface, where it redopes the body contact doping that is possibly already present.

Process 120 involves carrying out an implantation annealing step with a lowest possible thermal budget, so that the source implantation that usually comprises As/P hardly outdiffuses anymore, but the body contact implantation situated in the trench sidewall still expands somewhat in the direction of the centre of the mesa region in order to realize a good body connection (the body contact implantation should not outdiffuse too far, however, otherwise it would influence the opposite channel region and thus the threshold voltage).

The remaining processes steps are standard processes and familiar to the person skilled in the art.

The special feature of the structure, then, is that the trench that is connected to source potential anyway beneficially forms a large-area sidewall body contact by means of its sidewall; the mesa surface can essentially be utilized by the source contact.

In order to improve the trench sidewall contact, an additionally siliciding may optionally be provided, which may be applied to the surface of the mesa regions or to the surface of the trench sidewalls for example after process step 120.

The invention can preferably be applied to all trench transistors having one or more electrodes per trench, in particular from the dense trench regime with a mesa width smaller than the trench width.

Instead of the body contact implantation, it is also possible, as an alternative, to use a coating of the trench inner walls for example with dopants, for example boron-doped oxide or polysilicon. Therefore, an implantation process is not absolutely necessary for producing the body contact region.

The masking of the source implantation may also be effected in a self-aligned manner. A body contact region that reaches as deep as possible into the mesa region is advantageous for this purpose, e.g., by means of an additional recess as described above. The following steps are carried out: deposition of a planarizing auxiliary layer, etching-back of the auxiliary layer right into the trenches, a whole-area source implantation is effected in the cell array. If appropriate, the source implantation may additionally be masked in the edge region in order, for example, to improve the avalanche strength.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A trench transistor, having a semiconductor body in which a plurality of cell array trenches separated from one another by mesa regions are formed, comprising:
electrodes being embedded in the cell array trenches;
a source region, a body region and also a body contact region being provided in the mesa regions, and
the electrodes of a plurality of cell array trenches being at source potential; and
wherein at least some body contact regions are embodied in a form of a layer which forms a part of the upper region of the inner wall of a cell array trench, an electrode of which is at source potential, and whose horizontal extent is less than half of the horizontal extent of a mesa region.

2. The trench transistor of claim 1, comprising wherein at least some body contact regions adjoin the surface of the respective mesa region.

3. The trench transistor of claim 1, comprising wherein that a vertical extent of the source regions is less than a vertical extent of the body contact regions.

4. The trench transistor according of claim 1, comprising wherein the trench transistor comprises a dense trench transistor.

5. The trench transistor of claims 1, comprising wherein the cell array trenches in which electrodes at source potential are embedded alternate with cell array trenches in which electrodes at gate potential are embedded.

6. A trench transistor having a plurality of cell array trenches separated from one another by mesa regions, comprising:
electrodes being embedded in the cell array trenches;
a source region, a body region and also a body contact region being provided in the mesa regions; and
wherein at least some body contact regions are embodied in a form of a layer that forms a part of the upper region of the inner wall of a cell array trench, an electrode of which is at source potential, and whose horizontal extent is less than half of the horizontal extent of a mesa region.

7. The trench transistor of claim 6, comprising wherein at least some body contact regions adjoin the surface of the respective mesa region.

8. The trench transistor of claim 6, comprising wherein that a vertical extent of the source regions is less than a vertical extent of the body contact regions.

9. The trench transistor according of claim 6, comprising wherein the trench transistor is a dense trench transistor.

10. The trench transistor of claims 6, comprising wherein the cell array trenches in which electrodes at source potential are embedded alternate with cell array trenches in which electrodes at gate potential are embedded.

11. The trench transistor of claim 6, comprising wherein at least some body contact regions adjoin the surface of the respective mesa region, and wherein that a vertical extent of the source regions is less than a vertical extent of the body contact regions.

12. The trench transistor of claim 11, comprising wherein the trench transistor is a dense trench transistor.

13. The trench transistor of claim 12, comprising wherein the cell array trenches in which electrodes at source potential are embedded alternate with cell array trenches in which electrodes at gate potential are embedded.

14. A trench transistor, having a semiconductor body in which a plurality of cell array trenches separated from one another by mesa regions are formed, comprising:
means for providing electrodes embedded in the cell array trenches;
means for providing a source region, a body region and also a body contact region being provided in the mesa regions, the electrodes of a plurality of cell array trenches being at source potential; and
wherein at least some body contact regions are embodied in a form of a layer which forms a part of the upper region of the inner wall of a cell array trench, an electrode of which is at source potential, and whose horizontal extent is less than half of the horizontal extent of a mesa region

15. A method for fabricating source regions, body regions and also body contact regions in mesa regions of a trench transistor comprising:
forming the body contact regions in an upper region of the mesa regions in such a way that the body regions extend over the entire width of the mesa regions;
producing a cell array trench masking configured such that at least the cell array trenches in which electrodes at gate potential are provided are masked, but at least one region of each body region adjoining these cell array trenches is uncovered;
forming the body contact regions by applying dopants to the uncovered regions of the body regions, in particular the regions of the body regions which form the inner walls of the cell array trenches, using an oblique implantation or an inner wall coating process;
removing the cell array trench masking;
producing a cell array trench masking configured such that at least the cell array trenches in which electrodes at source potential are provided are masked, but at least one region of each body region and/or body contact region adjacent to these cell array trenches is uncovered; and
forming the source regions by applying dopants to the uncovered regions of the body regions using a normal implantation.

16. The method of claim 15, comprising wherein the cell array trench masking for masking the cell array trenches in which electrodes at source potential are provided is essentially complementary to the cell array trench masking for masking the cell array trenches in which electrodes at gate potential are provided.

17. The method of claim 15, comprising wherein the cell array trench masking for masking the cell array trenches in which electrodes at source potential are provided covers less than half of the width of the mesa regions adjoining these cell array trenches.

18. The method of claim 15, comprising wherein the source regions are formed using a vertical implantation process.

19. A method for fabricating source regions, body regions and also body contact regions in mesa regions of a trench transistor having electrodes being embedded in the cell array trenches, a source region, a body region and also a body contact region being provided in the mesa regions, and the electrodes of a plurality of cell array trenches being at source potential, and wherein at least some body contact regions are embodied in a form of a layer which forms a part of the upper region of the inner wall of a cell array trench, an electrode of which is at source potential, and whose horizontal extent is less than half of the horizontal extent of a mesa region comprising:
forming the body regions in the upper region of the mesa regions in such a way that the body regions extend over the entire width of the mesa regions;
producing a cell array trench masking configured such that at least the cell array trenches in which electrodes at gate potential are provided are masked, but at least one region of each body region adjoining these cell array trenches is uncovered;
forming the body contact regions by applying dopants to the uncovered regions of the body regions, in particular the regions of the body regions which form the inner walls of the cell array trenches, using an oblique implantation or an inner wall coating process;
removing the cell array trench masking;
producing a cell array trench masking configured such that at least the cell array trenches in which electrodes at source potential are provided are masked, but at least one region of each body region and/or body contact region adjacent to these cell array trenches is uncovered;
forming the source regions by applying dopants to the uncovered regions of the body regions using a normal implantation.

20. The method of claim 19, comprising wherein the cell array trench masking for masking the cell array trenches in which electrodes at source potential are provided is essentially complementary to the cell array trench masking for masking the cell array trenches in which electrodes at gate potential are provided.

21. The method of claim 20, comprising wherein the cell array trench masking for masking the cell array trenches in which electrodes at source potential are provided covers less than half of the width of the mesa regions adjoining these cell array trenches.

22. The method of claim 21, comprising wherein the source regions are formed using a vertical implantation process.

23. A trench transistor comprising:
a semiconductor body in which a plurality of cell array trenches separated from one another by mesa regions are formed, electrodes being embedded in the cell array trenches; a source region, a body region and also a body contact region in each case being provided in the mesa regions; and
the electrodes of a plurality of cell array trenches being at source potential, comprising at least some body contact regions are embodied in the form of a layer which forms a part of the upper region of the inner wall of a cell array trench, the electrode of which is at source potential, and whose horizontal extent is less than half of the horizontal extent of a mesa region, all the cell array trenches having the same dimensions, and insulations which are provided in the cell array trenches and electrically insulate the electrodes from the semiconductor body being of thickened configuration in the lower regions of the cell array trenches.
